(19) United States
(12) Patent Application Publication
(10) Pub. No.: US 2002/0094590 A1
(43) Pub. Date: Jul. 18, 2002

(54) Method for manufacturing semiconductor laser module, semiconductor laser module and Raman amplifier

(75) Inventors: Yuichiro Irie, Tokyo (JP); Takeshi Aikiyo, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: THE FURUKAWA ELECTRIC CO., LTD., Tokyo (JP)

(21) Appl. No.: 09/985,761

(22) Filed: Nov. 6, 2001

(30) Foreign Application Priority Data
Nov. 6, 2000 (JP) 2000-338109

(51) Int. Cl. H01L 21/66; G01R 31/26; H01L 21/00

(52) U.S. Cl. 438/14; 438/31

(57) ABSTRACT

First of all, an optical system consisting of first and second lenses 6, 7 is positioned in front of a semiconductor laser diode 1 such that the optical coupling efficiency of a laser beam emitted from the front facet of a semiconductor laser diode 1 with a second optical fiber 3 will be maximized. The optical coupling efficiency of the laser beam with the second optical fiber 3 may be measured, for example, using an optical power meter 9 connected to the end of the second optical fiber 3. Subsequently, a first optical fiber 2 including a diffraction grating K is positioned behind the semiconductor laser diode 1 such that the output of the laser beam emitted from the front facet of the semiconductor laser diode 1 will be maximized. The output of the laser beam is measured by the optical power meter 9 as in the optical coupling efficiency.

### BACKGROUND OF THE INVENTION

The present invention relates to a method of manufacturing a semiconductor laser module, a semiconductor laser module produced by this method and a Raman amplifier comprising this semiconductor laser module.

There is known a semiconductor laser module which is used as a signal light source or an pumping light source for optical amplifier and which comprises a reflection member located behind a semiconductor laser diode.

### SUMMARY OF THE INVENTION

The present invention provides a method of manufacturing a semiconductor laser module comprising a semiconductor laser diode for emitting a laser beam, an optical system for optically coupling a laser beam emitted from one facet of the semiconductor laser diode to a optical output fiber and a reflection member for reflecting a predetermined wavelength of the laser beam emitted from the other facet of said semiconductor laser diode back to said semiconductor laser diode, said method comprising a step of positioning said reflection member relative to the other facet of said semiconductor laser diode depending on the characteristics of the laser beam emitted from said one facet of said semiconductor laser diode.

The present invention provides a semiconductor laser module comprising a semiconductor laser diode for emitting a laser beam, an optical system for optically coupling a laser beam emitted from one facet of the semiconductor laser diode to an optical output fiber and a reflection member for reflecting a predetermined wavelength of the laser beam emitted from the other facet of said semiconductor laser diode back to said semiconductor laser diode, manufactured by a method comprising a step of positioning said reflection member relative to the other facet of said semiconductor laser diode depending on the characteristics of the laser beam emitted from said one facet of said semiconductor laser diode.

The present invention provides a Raman amplifier comprising a semiconductor laser module comprising a semiconductor laser diode for emitting a laser beam, an optical system for optically coupling a laser beam emitted from one facet of the semiconductor laser diode to a optical output fiber and a reflection member for reflecting a predetermined wavelength of the laser beam emitted from the other facet of said semiconductor laser diode back to said semiconductor laser diode, manufactured by a method comprising a step of positioning said reflection member relative to the other facet of said semiconductor laser diode depending on the characteristics of the laser beam emitted from said one facet of said semiconductor laser diode, and a control unit for controlling said semiconductor laser module.

### BRIEF DESCRIPTION OF THE DRAWINGS

FIGS. 1A and B illustrate a method of manufacturing a semiconductor laser module according to the first embodiment of the present invention.

FIGS. 2A and B illustrate a method of manufacturing a semiconductor laser module according to the second embodiment of the present invention.

FIG. 3 is a sectional view of a semiconductor laser module according to the third embodiment of the present invention.

FIG. 4 is a block diagram showing the layout of a Raman amplifier according to the fourth embodiment of the present invention.

FIG. 5 is a diagrammatically sectional view showing a semiconductor laser module according to the related art.

### DETAILED DESCRIPTION

Several embodiments of the present invention will now be described in comparison with the related art with reference to the accompanying drawings.

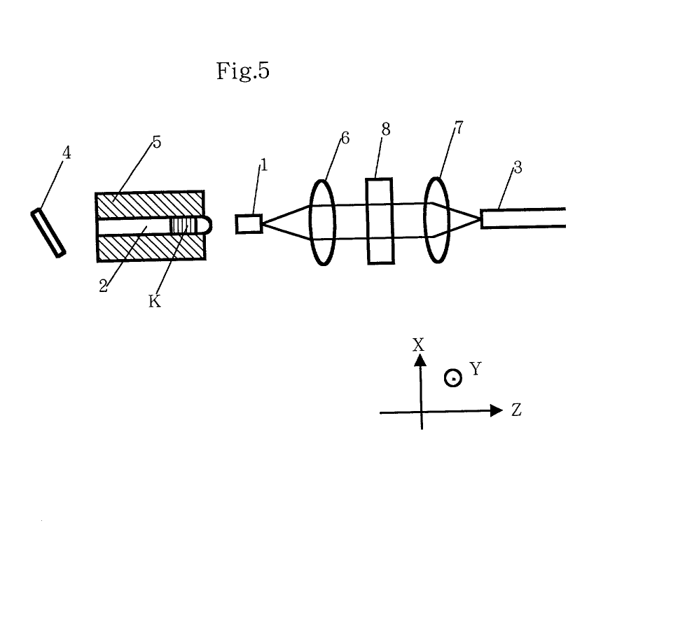

A semiconductor laser module including a reflection member disposed at the rear side of a semiconductor laser diode is disclosed, for example, in Japanese Patent Laid-Open Application No. 2000-208869. FIG. 5 is a diagrammatically sectional view showing a semiconductor laser module according to the related art which relates to the present invention.

As shown in FIG. 5, this semiconductor laser module has a semiconductor laser diode 1 for emitting a laser beam, a first optical fiber 2 including a diffraction grating K such as FBG formed therein for receiving the laser beam emitted from the rear facet of the semiconductor laser diode 1 (left side in FIG. 5) and feeding it back to the semiconductor laser diode 1, a second optical fiber 3 for receiving the laser beam emitted from the front facet of the semiconductor laser diode 1 (right side in FIG. 5), a photodiode 4 for receiving a monitoring laser beam passed through the first optical fiber 2.

The first optical fiber 2 is formed into a lensed fiber with a lensed tip end on the side of the semiconductor laser diode 1 insertingly supported in a first ferrule 5. At this time, the first optical fiber 2 is positioned relative to the semiconductor laser diode 1 such that the tip end of the first optical fiber 2 is opposed to the rear facet, and more particularly to a portion corresponding to the end of the active layer of the semiconductor laser diode. In such an arrangement, an optical resonance occurs between the front facet of the semiconductor laser diode 1 and the diffraction grating K of the first optical fiber 2 through the active layer of the semiconductor laser diode 1. Thus, the semiconductor laser diode 1 will emit from the front facet thereof a laser beam having the same center wavelength as the reflection center wavelength of the diffraction grating K.

In front of the semiconductor laser diode 1, there are fixedly located a first lens (or collimating lens) 6 for collimating the laser beam emitted from the front facet of the semiconductor laser diode 1 and a second lens (or condensing lens) 7 for condensing said collimated laser beam into the second optical fiber 3.

The second optical fiber 3 is disposed so that the tip end thereof is opposed to the front facet of the semiconductor laser diode 1 and delivers the laser beam emitted from the front facet of the semiconductor laser diode 1 to external optical elements.

Between the first lens 6 and the second lens 7, there is disposed an optical isolator 8 for transmitting a laser beam traveling only from the front facet of the semiconductor element 1 toward the corresponding tip of the second optical fiber 3 (or only from the left to the right in FIG. 5).

The laser beam emitted from the front facet of the semiconductor laser diode 1 is collimated by the first lens 6 and transmitted through the optical isolator 8 to the second lens 7 where it is condensed to be coupled to the second optical fiber which delivers the laser beam.

The laser beam emitted from the rear facet of the semiconductor laser diode 1 pass through the first optical fiber 2 to be received by a photodiode 4. By calculating the amount of light received by the photodiode 4, the optical output of the semiconductor 1 may be adjusted.

Such an arrangement did not propose any concrete process relating to how a reflection member such as an optical fiber including a diffraction grating for reflecting a predetermined wavelength of a laser beam should optimally be positioned at the rear facet side of the semiconductor laser diode. Therefore, it was difficult to produce a semiconductor laser module having a second optical fiber for outputting a laser beam having its superior output characteristics such as wavelength stability and so on.

In the related art, the optical fiber was generally positioned while observing the optical output characteristics in that optical fiber.

In such a semiconductor laser module as described above, however, it is the laser beam outputted from the second optical fiber that should be used in the desired application. Thus, it is meaningless to improve the optical output characteristics in the first optical fiber unless those of the second optical fiber are improved.

In addition, because the first optical fiber 2 is lacking in length and cannot be used to take the laser beam outside of the package as in the second optical fiber coming outside as a pigtail fiber, the operation of positioning the first optical fiber 2 or taking the optical output from the first optical fiber 2 raises various problems and is also very troublesome.

To overcome the aforementioned problems, the present invention provides a method of manufacturing a semiconductor laser module which can output a laser beam superior in optical output characteristics, a semiconductor laser module and a Raman amplifier.

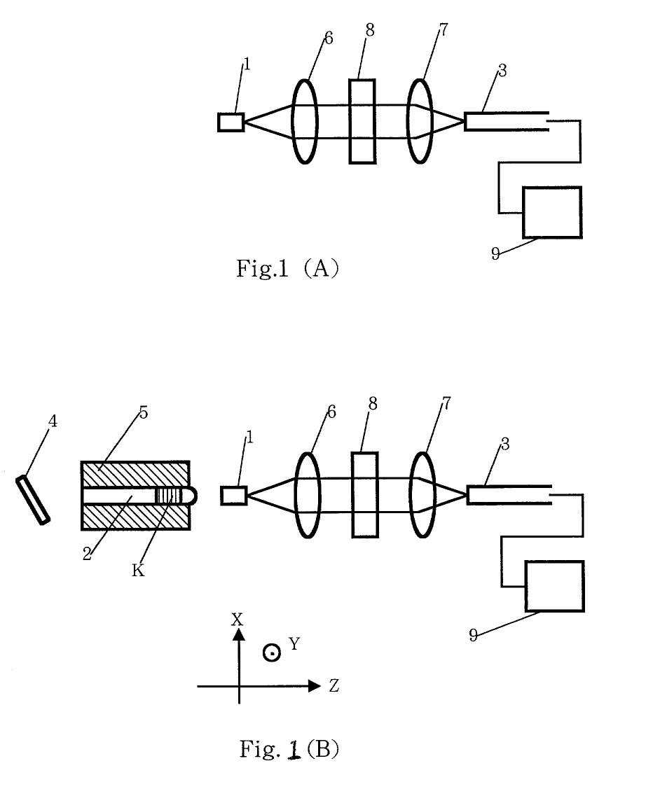

FIGS. 1A and B illustrate a method of manufacturing a semiconductor laser module according to the first embodiment of the present invention. Note that the parts similar to those of FIG. 5 are denoted by the same reference numerals.

First of all, as shown in FIG. 1A, an optical system consisting of first and second lenses 6, 7 is positioned at the front facet side of a semiconductor laser diode 1 such that the optical coupling efficiency of the laser beam emitted from the front facet of the semiconductor laser diode 1 to a second optical fiber 3 will be maximized (step 1).

The optical coupling efficiency of the laser beam to the second optical fiber 3 may be measured, for example, using an optical power meter 9 connected to the end of the second optical fiber 3.

Next, as shown in FIG. 1B, a first optical fiber 2 including a diffraction grating K is fixedly positioned at the rear facet side of the semiconductor laser diode 1 such that the optical output of the laser beam emitted from the front facet of the semiconductor laser diode 1 will be maximized (step 2). The output of the laser beam is measured by the optical power meter 9 connected to the end of the second optical fiber 3 as in the optical coupling efficiency.

The first optical fiber 2 is properly positioned by adjustingly moving a ferrule 5 supporting the first optical fiber 2 in the directions of three axes X, Y and Z while chucking the ferrule 5. Further, a photodiode 4 may preferably be positioned after the step 2 such that it will not interfere with the positioning of the optical fiber 2 and can efficiently receive the laser beam from the optical fiber 2.

According to the first embodiment of the present invention, the first optical fiber 2 that is a reflection member is positioned at the rear facet side of the semiconductor laser diode 1 such that the output of the laser beam emitted from the front facet of the semiconductor laser diode 1 will be maximized. Thus, the first optical fiber 2 can optimally be positioned. As a result, there can be produced a semiconductor laser module which is superior in optical output characteristics such as wavelength stability and which can output a high-intensity laser beam.

In addition, since the step 2 is carried out after the optical coupling efficiency of the laser beam with the second optical fiber 3 has been increased in the step 1, the separability of the optical power meter 9 can be improved with the first optical fiber 2 being more accurately positioned, in the step 2.

Further, the step 1 may be carried out after the step 2.

For example, the first lens 6, optical isolator 8 and second lens 7 may be fixedly mounted after the optical fiber 2 has been aligned in such a state that the first lens 6, second lens 7 and optical fiber 3 are temporarily fixed.

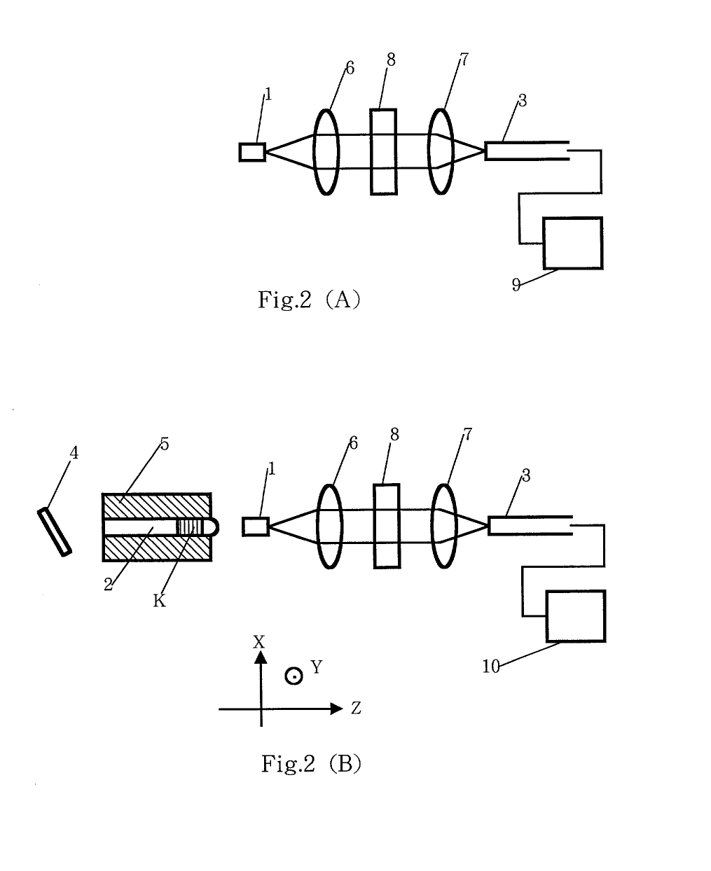

FIGS. 2A and B illustrate a method of manufacturing a semiconductor laser module according to the second embodiment of the present invention.

First of all, as shown in FIG. 2A, an optical system consisting of first and second lenses 6, 7 is positioned at the front facet side of a semiconductor laser diode 1 such that the optical coupling efficiency of the laser beam emitted from the front facet of the semiconductor laser diode 1 to a second optical fiber 3 will be maximized (step 3). The optical coupling efficiency of the laser beam to the second optical fiber 3 may be measured, for example, using an optical power meter 9 connected to the end of the second optical fiber 3.

Next, as shown in FIG. 2B, the first optical fiber 2 is fixedly positioned at the rear facet side of the semiconductor laser diode 1 such that the wavelength of the laser beam emitted from the front facet of the semiconductor laser diode 1 will be equal to the wavelength reflected by the diffraction grating K in the first optical fiber 2 (step 4).

The wavelength of the laser beam may be measured, for example, using an optical spectrum analyzer 10 connected to the end of the second optical fiber 3. The optical spectrum analyzer 10 may be replaced by a wavemeter.

The first optical fiber 2 is properly positioned by adjustingly moving a ferrule 5 supporting the first optical fiber 2 in the directions of three axes X, Y and Z while chucking the ferrule 5.

According to the second embodiment of the present invention, the first optical fiber 2 is positioned at the rear facet side of the semiconductor laser diode 1 such that the wavelength of the laser beam emitted from the front facet of the semiconductor laser diode 1 will be equal to the wavelength reflected by the diffraction grating K in the first optical fiber 2. Thus, the first optical fiber 2 that is a reflection member can optimally be positioned. As a result, there can be produced a semiconductor laser module which is superior in optical output characteristics such as wavelength stability.

In addition, since the step 4 is carried out after the optical coupling efficiency of the laser beam to the second optical fiber 3 has been increased in the step 3, the separability of the optical spectrum analyzer 9 can be improved with the first optical fiber 2 being more accurately positioned, in the step 4.

Further, the step 3 may be carried out after the step 4 as in the first embodiment in which the step 1 may be carried out after the step 2.

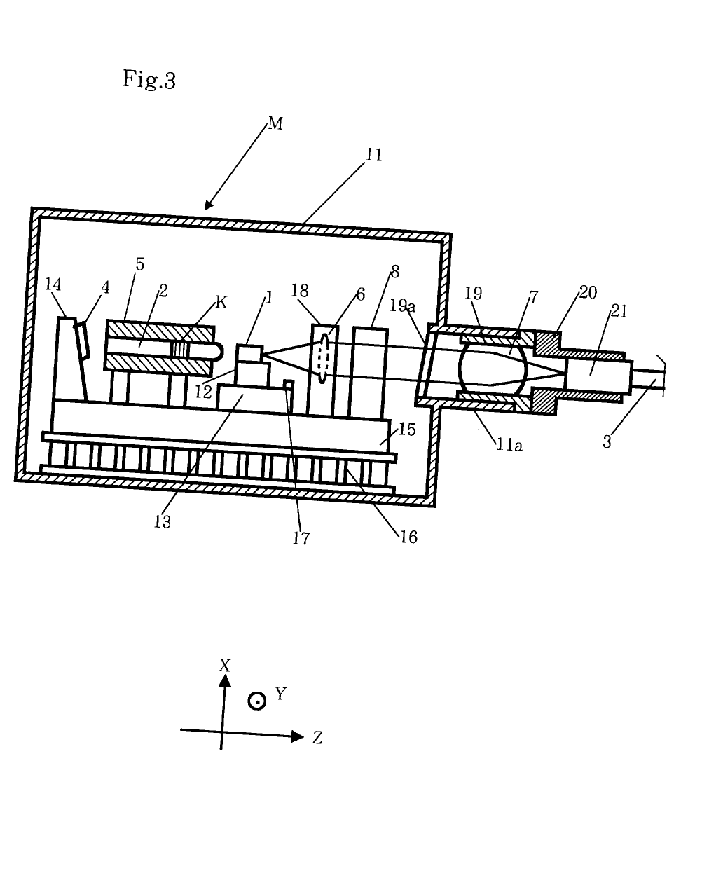

FIG. 3 is a sectional view showing a semiconductor laser module according to the third embodiment of the present invention which is manufactured according to the method described in connection with the first or second embodiment of the present invention. As shown in FIG. 3, semiconductor laser module M has a hermetically sealed package 11, a semiconductor laser diode 1 located in the package 11 for emitting a laser beam, a first optical fiber 2 with lensed tip end and a diffraction grating K formed therein for receiving the laser beam emitted from the rear facet of the semiconductor laser diode 1 (left side in FIG. 1) and for reflecting only a predetermined wavelength thereof, and a second optical fiber 3 for receiving the laser beam emitted from the front facet of the semiconductor laser diode 1 (right side in FIG. 1) and for externally delivering it.

The semiconductor laser diode 1 is fixedly mounted on a heat sink 12 which is in turn fixedly mounted on a chip carrier 13.

The first optical fiber 2 is held by an anchoring member 50 through a ferrule 5 which is disposed at the rear facet side of the semiconductor laser diode 1.

A photodiode 4 is fixedly mounted on a photodiode carrier 14. The chip carrier 13 and photodiode carrier 14 are mounted on a base 15 below which a cooling device 16 comprising Peltier elements is disposed. Temperature rise by heat from the semiconductor laser diode 1 is sensed by a thermistor 17 on the chip carrier 13 and used to control the cooling device so as to maintain the temperature sensed by the thermistor 17 constant. Thus, the laser output from the semiconductor laser diode 1 can be stabilized.

At the front facet side of the semiconductor laser diode 1 on the base 15, there is located a first lens 6 for collimating the laser beam emitted from the semiconductor laser diode 1. The first lens 6 is held by a first lens holder 18 on the base 15.

The package 11 includes a flange 11a formed thereon on one side, which flange 11a houses a window 19a for receiving the beam that passed through the first lens 6 and a second lens 7 for condensing the laser beam. The second lens 7 is held by a second lens holder 19 which is fixed at the outer end of the flange 11a by YAG laser welding after being position thereon. A metallic sleeve 20 is fixedly mounted on the outer end of the second lens holder 19 by YAG laser welding, fixedly supporting the second optical fiber 3. The second optical fiber 3 is held by a ferrule 21 which is fixedly mounted in the sleeve 20 by laser welding after being positioned along the optical axis (or in Z-axis direction). The sleeve 20 is YAG laser welded to the outer end of the second lens holder 19 after being positioned a plane perpendicular to the optical axis of the optical fiber 3 (X-Y plane).

Thus, the position can be determined both along the optical axis of the optical fiber 3 and in the plane perpendicular thereto (X-Y plane).

In addition, between the semiconductor laser diode 1 and the second optical fiber 2 for output, there is located an optical isolator 8 for blocking reflected laser beam from the second optical fiber 3.

Since the first optical fiber 2 with the diffraction grating K is disposed between the semiconductor laser diode 1 and the photodiode 4, there will be created an optical resonance between the front facet of the semiconductor laser diode 1 and the diffraction grating K in the first optical fiber 2, thereby causing a semiconductor laser diode 1 to emit a laser beam having a predetermined wavelength from the front facet thereof. The laser beam emitted from the front facet of the semiconductor laser diode 1 is collimated by the first lens 6 and pass through the optical isolator 8 before being condensed by the second lens 7 into the end of the second optical fiber 3 held by the ferrule 21, from which the laser beam is externally delivered.

On the other hand, the laser beam emitted from the rear facet of the semiconductor laser diode 1 and passed through the first optical fiber 2 is received by the photodiode 4. By calculating the amount of light received by the photodiode 4, the optical output of the laser beam emitted from the front facet of the semiconductor laser diode 1 can be adjusted.

Further, the optical system for optically coupling the laser beam from the front facet of the semiconductor laser diode 1 to the optical fiber is not limited to such a two-lens system as described herein, but may be in any of various other forms such as a condensing one-lens system or a fiber lens formed on the tip end of an optical fiber.

Since the semiconductor laser module according to the third embodiment of the present invention is manufactured according to the method as described in connection with the first or second embodiments, it can output a laser beam of superior wavelength stability.

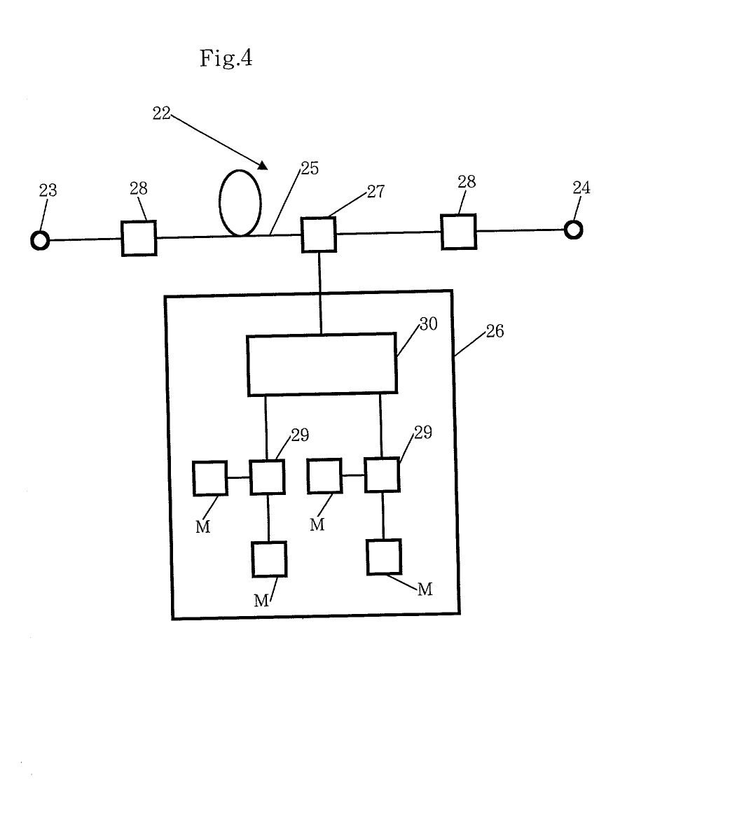

FIG. 4 is a block diagram showing the layout of a Raman amplifier according to the fourth embodiment of the present invention. As shown in FIG. 4, the Raman amplifier 22 according to the fourth embodiment of the present invention has an input port 23 for receiving a signal light, an output port 24 for outputting the signal light, an optical amplification fiber 25 for transmitting the signal light between the input port 23 and the output port 24, an pumping light generating unit 26 for generating an pumping beam, and a WDM coupler 27 for combining the pumping light generated by the pumping beam generating unit 26 with the signal light transmitted by the optical amplification fiber 25. Between the input port 23 and the WDM coupler 27 and between the output port 24 and the WDM coupler 27, there are respectively disposed optical isolators 28 for transmitting the signal light only in the direction from the input port 23 toward the output port 24.

The pumping light generating unit 26 has semiconductor laser modules M constructed according to the third embodiment of the present invention as described, polarization-multiplexing couplers 29 each for multiplexing the laser beams emitted from the respective semiconductor laser modules M of the same wavelength but of the orthogonal polarization each other, and a WDM coupler 30 for multiplexing the output laser beams from the respective polarization-multiplexing couplers 29. The polarization multiplexing by the polarization-multiplexing couplers 29 is to reduce the degree of polarization (DOP) since the Raman amplification gain depends on polarization.

Further, instead of such a polarization multiplexing, a depolarizer such as a polarization maintaining fiber may be used to decrease DOP in the output beams from a semiconductor laser modules M, in such a way that it receives an incident polarized light with an angle of 45 degree relative to its polarization maintaining axis.

The pumping beams emitted from the respective semiconductor laser modules M are polarization multiplexed by the corresponding polarization-multiplexing couplers 29 for the same wavelength. The output beams of the polarization-multiplexing couplers 29 are multiplexed by the WDM coupler 30 to form the output beam of the pumping beam generating unit 26.

The pumping beam generated by the pumping light generating unit 26 is optically coupled to the optical amplification fiber 25 by the WDM coupler 27. On the other hand, the signal light inputted through the input port 23 is combined with the pumping beam and Raman amplified in the optical fiber 25. Thereafter, the amplified signal light is passed through the WDM coupler 27 and outputted through the output port 24.

The Raman amplifier 22 according to the fourth embodiment of the present invention can provide any desired stable Raman gain since it uses the semiconductor laser modules M which can emit a high-intensity laser beam with superior wavelength stability.

The present invention is not limited to the aforementioned embodiments, but may be carried out in any of various other forms without departing from the scope of the invention as defined in the appending claims.

For example, the reflection member may be a total reflection mirror with a filter. In addition, there may be used a support member which is formed by integrally combining the ferrule 5 holding the first optical fiber 2 with the photodiode carrier 14 fixedly supporting the photodiode 4.

1. A method of manufacturing a semiconductor laser module comprising a semiconductor laser diode for emitting a laser beam, an optical system for optically coupling a laser beam emitted from one facet of the semiconductor laser diode to an optical output fiber and a reflection member for reflecting a predetermined wavelength of the laser beam emitted from the other facet of said semiconductor laser diode back to said semiconductor laser diode, said method comprising a step of positioning said reflection member relative to the other facet of said semiconductor laser diode depending on the characteristics of the laser beam emitted from said one facet of said semiconductor laser diode.

2. The method of manufacturing a semiconductor laser module according to claim 1 wherein said reflection member is positioned such that the output of the laser beam emitted from said one facet of said semiconductor laser diode will be maximized.

3. The method of manufacturing a semiconductor laser module according to claim 1 wherein said reflection member is positioned such that the wavelength of the laser beam emitted from said one facet of said semiconductor laser diode will be equal to a desired wavelength.

4. The method of manufacturing a semiconductor laser module according to claim 1 wherein after said optical system has been positioned relative to said one facet of said semiconductor laser diode, said reflection member is positioned such that the optical coupling efficiency of the laser beam emitted from said one facet of said semiconductor laser diode with said optical fiber will be maximized.

5. The method of manufacturing a semiconductor laser module according to claim 1 wherein said reflection member is an optical fiber with a lensed tip end and formed with a diffraction grating for reflecting a predetermined wavelength of a laser beam.

6. A semiconductor laser module comprising a semiconductor laser diode for emitting a laser beam, an optical system for optically coupling a laser beam emitted from one facet of the semiconductor laser diode to an optical output fiber and a reflection member for reflecting a a predetermined wavelength of the laser beam emitted from the other facet of said semiconductor laser diode back to said semiconductor laser diode, manufactured by a method comprising a step of positioning said reflection member relative to the other facet of said semiconductor laser diode depending on the characteristics of the laser beam emitted from said one facet of said semiconductor laser diode.

7. A Raman amplifier comprising a semiconductor laser module comprising a semiconductor laser diode for emitting a laser beam, an optical system for optically coupling a laser beam emitted from one facet of the semiconductor laser diode to an optical output fiber and a reflection member for reflecting a predetermined wavelength of the laser beam emitted from the other facet of said semiconductor laser diode back to said semiconductor laser diode, manufactured by a method comprising a step of positioning said reflection member relative to the other facet of said semiconductor laser diode depending on the characteristics of the laser beam emitted from said one facet of said semiconductor laser diode, and a control unit for controlling said semiconductor laser module.
